(19) United States
(12) Patent Application Publication
(10) Pub. No.: US 2026/0371813 A1
(43) Pub. Date: Nov. 19, 2026

(54) DISPLAY MODULE AND DISPLAY APPARATUS

(71) Applicant: BOE TECHNOLOGY GROUP CO., LTD., Beijing (CN)

(72) Inventors: Jianhua DU, Beijing (CN); Ying ZHOU, Beijing (CN); Minghua XUAN, Beijing (CN); Ce NING, Beijing (CN); Feng GUAN, Beijing (CN); Yang LV, Beijing (CN); Shunhang ZHANG, Beijing (CN); Dongni LIU, Beijing (CN); Haoliang ZHENG, Beijing (CN); Li XIAO, Beijing (CN); Linfeng LI, Beijing (CN); Qiuhua MENG, Beijing (CN); Jianlong LIU, Beijing (CN); Yicheng LIN, Beijing (CN); Qingkai ZHANG, Beijing (CN); Huanxin YUE, Beijing (CN)

(21) Appl. No.: 19/154,401

(22) PCT Filed: Mar. 31, 2023
(86) PCT No.: PCT/CN2023/085562

§ 371 Date: Aug. 7, 2025

(51) Int. Cl. H10H 29/49; H10H 29/32; H10H 29/80

(52) U.S. Cl. CPC H10H 29/49; H10H 29/32; H10H 29/8323

(57) ABSTRACT

A display module, comprising a base substrate (11), a driving circuit layer and a first functional layer (3), the driving circuit layer being arranged on a side of the base substrate (11). The first functional layer (3) is arranged on the side of the base substrate (11) away from the driving circuit layer, or between the base substrate (11) and the driving circuit layer, or on the side of the driving circuit layer away from the base susbtrate (11), and the first functional layer (3) can release static electricity generated during the process of manufacturing the display module, thus avoiding the problem of circuit damage to the display module caused by electrostatic discharge.

### CROSS REFERENCE TO RELATED APPLICATIONS

The present disclosure is the U.S. national phase application of International Application No. PCT/CN2023/085562, filed on Mar. 31, 2023, the content of which is incorporated herein by reference in its entirety for all purposes.

### TECHNICAL FIELD

The present disclosure relates to the field of display technology, in particular, to a display module and a display apparatus.

### BACKGROUND

Full screen display can significantly increase the screen-to-body ratio without changing the size of the terminal, providing users with a larger screen area and a more immersive visual impact experience. Therefore, achievement of full screen display has become a development trend for different terminal devices.

At present, the display module controls each light-emitting unit by providing the separate chip for light-emitting unit, resulting in a high cost. Through driving based on an array substrate, it is possible to control the light-emitting units with a single chip, greatly reducing control costs. However, this structure can lead to poor anti-static performance of the display module, which can easily cause circuit damage.

It should be noted that the information disclosed in the above section is only intended to enhance the understanding of the background of the present disclosure, and thus can include information that does not constitute the prior art already known to those skilled in the art.

### SUMMARY

According to one aspect of the present disclosure, a display module is provided. The display module includes a base substrate, a driving circuit layer, a first functional layer, and a light-emitting substrate, wherein the driving circuit layer is arranged on a side of the base substrate; the first functional layer is arranged on a side of the base substrate away from the driving circuit layer, between the base substrate and the driving circuit layer, or on a side of the driving circuit layer away from the base substrate, wherein the first functional layer can at least release static electricity generated by the display module; the light-emitting substrate is arranged on the side of the driving circuit layer away from the base substrate, and the light-emitting substrate includes multiple light-emitting units.

In some embodiments of the present disclosure, the first functional layer is a p-type doped amorphous silicon layer, an n-type doped amorphous silicon layer, a conductive low-temperature polycrystalline silicon layer, or a transparent electrode layer.

In some embodiments of the present disclosure, in the case that the first functional layer is the transparent electrode layer, the p-type doped amorphous silicon layer, the n-type doped amorphous silicon layer, or the conductive low-temperature polycrystalline silicon layer, the first functional layer is arranged on the side of the base substrate away from the driving circuit layer or between the base substrate and the driving circuit layer.

In some embodiments of the present disclosure, in the case that the first functional layer is arranged on the side of the base substrate away from the driving circuit layer, a first buffer layer is provided between the first functional layer and the base substrate.

In some embodiments of the present disclosure, in the case that the first functional layer is arranged between the base substrate and the driving circuit layer, a second buffer layer is provided between the base substrate and the first functional layer, and a third buffer layer is provided between the first functional layer and the driving circuit layer.

In some embodiments of the present disclosure, the second functional layer is an amorphous silicon layer, a p-type doped amorphous silicon layer, an n-type doped amorphous silicon layer, or a conductive low-temperature polycrystalline silicon layer.

In some embodiments of the present disclosure, the driving circuit layer includes a driving circuit, a data signal line, a common ground signal line, and a power signal line, the driving circuit and the light-emitting unit are connected in series between the power signal line and the common ground signal line, and an output end of the data signal line is connected to the driving circuit.

In some embodiments of the present disclosure, the driving circuit layer includes a transistor layer, the transistor layer includes a thin film transistor, and the thin film transistor is a double gate thin film transistor.

In some embodiments of the present disclosure, the driving circuit layer further includes a first metal layer, the first metal layer is arranged on a side of the transistor layer away from the base substrate, and the data signal line, the power signal line, and the common ground signal line are located in the first metal layer.

In some embodiments of the present disclosure, the first metal layer further includes a first conductive part, the first conductive part is connected to the data signal line, the first conductive part is located at an edge of the first metal layer, and the first conductive part is configured to be connected with a leading-out line.

In some embodiments of the present disclosure, the first functional layer is connected to the power signal line or the common ground signal line through a via hole.

In some embodiments of the present disclosure, the driving circuit layer further includes an interlayer dielectric layer, and the interlayer dielectric layer is provided between the first metal layer and the transistor layer.

In some embodiments of the present disclosure, the display module further includes a second metal layer, the second metal layer is arranged on a side of the interlayer dielectric layer away from the base substrate, the second metal layer includes a second pad and a third pad, the second pad is connected to the power signal line and the common ground signal line respectively through via holes, and the third pad is connected to a source or a drain of the thin film transistor through a via hole.

In some embodiments of the present disclosure, the second metal layer further includes a first pad, the first pad is stacked on a side of the first conductive part away from the base substrate, and the first pad is configured to be connected with the leading-out line.

In some embodiments of the present disclosure, the display module further includes a first planarization layer, the first planarization layer is provided between the second metal layer and the first metal layer, the first planarization layer partially covers the first metal layer and the interlayer dielectric layer, and exposes the first conductive part.

In some embodiments of the present disclosure, the display module further includes a first protective layer, the first protective layer is provided between the first planarization layer and the second metal layer, the first protective layer covers the first planarization layer and the interlayer dielectric layer, and exposes the first conductive part.

In some embodiments of the present disclosure, the display module further includes a second protective layer, the second protective layer is arranged on a side of the second metal layer away from the base substrate, and the second protective layer covers the first protective layer, a portion of the first pad, a portion of the second pad, and a portion of the third pad.

In some embodiments of the present disclosure, the display module further includes a second planarization layer, the second planarization layer is arranged on a side of the second protective layer away from the base substrate, the second planarization layer covers the second protective layer, a surface of the second planarization layer away from the base substrate is flat, and the second planarization layer exposes a portion of the third pad and a portion of the second pad.

In some embodiments of the present disclosure, the display module further includes a third protective layer, the third protective layer is arranged on a side of the second planarization layer away from the base substrate, and the third protective layer exposes a portion of the third pad and a portion of the second pad.

In some embodiments of the present disclosure, in the case that the first functional layer is the transparent electrode layer, the first functional layer is provided between the third protective layer and the second planarization layer.

In some embodiments of the present disclosure, the display module further includes a leading-out line, the leading-out line is bound to the first pad, and extends along a side surface of the driving circuit layer and a side surface of the base substrate to a side of the base substrate away from the driving circuit, and where the leading-out line is formed by laser etching a sputtering layer.

According to another aspect of the present disclosure, a display apparatus is provided. The display apparatus includes the display module provided by any of the aspects of the present disclosure.

It should be understood that the general description in the above and the detailed description in the following are only illustrative and explanatory, and do not limit the present disclosure.

### BRIEF DESCRIPTION OF THE DRAWINGS

The drawings, which are incorporated in and constitute a part of this specification, illustrate embodiments consistent with the present disclosure and serve together with the specification to explain principles of the present disclosure. It is apparent that the drawings in the following description are only some embodiments of the present disclosure, and for those of ordinary skill in the art, other drawings can also be obtained from these drawings without creative efforts.

FIG. 1 is a front schematic diagram of a display module according to embodiments of the present disclosure.

FIG. 2 is a schematic diagram of a driving principle of a display module according to embodiments of the present disclosure.

FIG. 3 is a rear schematic diagram of a display module when a first functional layer is arranged on a rear surface of a base substrate according to embodiments of the present disclosure.

FIG. 4 is a rear schematic diagram of a display module when a first functional layer is arranged on a front surface of a base substrate according to embodiments of the present disclosure.

FIGS. 5 to 9 are schematic diagrams of a production process of a display module when a first functional layer is a TIO layer according to embodiments of the present disclosure.

FIG. 10 is a cross-sectional schematic diagram of a display module when a first functional layer is a TIO layer according to embodiments of the present disclosure.

FIG. 11 is a cross-sectional schematic diagram of a display module when a first functional layer is a TIO layer according to embodiments of the present disclosure.

FIG. 12 is a cross-sectional schematic diagram of a display module when a first functional layer is a TIO layer according to embodiments of the present disclosure.

FIG. 13 is a cross-sectional schematic diagram of a display module when a first functional layer is a p-type doped amorphous silicon layer or an n-type doped amorphous silicon layer according to embodiments of the present disclosure.

FIG. 14 is a cross-sectional schematic diagram of a display module when a first functional layer is a p-type doped amorphous silicon layer or an n-type doped amorphous silicon layer according to embodiments of the present disclosure.

FIG. 15 is a cross-sectional schematic diagram of a display module when a first functional layer is a p-type doped amorphous silicon layer or an n-type doped amorphous silicon layer according to embodiments of the present disclosure.

FIG. 16 is a cross-sectional schematic diagram of a display module when a first functional layer is a p-type doped amorphous silicon layer or an n-type doped amorphous silicon layer according to embodiments of the present disclosure.

FIG. 17 is a cross-sectional schematic diagram of a display module when a first functional layer is a conductive low-temperature polycrystalline silicon layer according to embodiments of the present disclosure.

FIG. 18 is a cross-sectional schematic diagram of a display module when a first functional layer is a conductive low-temperature polycrystalline silicon layer according to embodiments of the present disclosure.

FIG. 19 is a cross-sectional schematic diagram of a display module when a first functional layer is located on a rear surface of a base substrate according to embodiments of the present disclosure.

FIG. 20 is a cross-sectional schematic diagram of a display module when a first functional layer is located between a base substrate and a driving circuit layer according to embodiments of the present disclosure.

FIG. 21 is a cross-sectional schematic diagram of a display module when a first functional layer is located on a side of a driving circuit layer away from a base substrate according to embodiments of the present disclosure.

### EXPLANATIONS OF REFERENCE NUMERALS

1—array substrate, 11—base substrate, 101—first surface, 1011—display area, 102—second surface, 1021—gap, 120—first gate layer, 121—first gate insulation layer, 122—active layer, 123—second gate insulation layer, 124—second gate layer, 125—interlayer dielectric layer, 126—first metal layer, 1261—source, 1262—data signal line, 1263—power signal line, 1264—common ground signal line, 1265—first conductive part, 1266—drain, 1271—first planarization layer, 1272—second planarization layer, 1281—first protective layer, 1282—second protective layer, 1283—third protective layer, 1201—driving circuit, 13—second metal layer, 131—first pad, 132—second pad, 133—third pad, 2—leading-out line, 21—fan-out leading segment, 22—binding leading segment, 3—first functional layer, 4—second functional layer, 5—first buffer layer, 6—second buffer layer, 7—third buffer layer, 8—group of light-emitting units, 81—light-emitting unit.

### DETAILED DESCRIPTION

Example embodiments will now be described more fully with reference to the drawings. Example embodiments, however, can be embodied in a variety of forms and should not be construed as being limited to examples set forth herein. Instead, these embodiments are provided so that the present disclosure will be thorough and complete, and will fully convey concepts of the example embodiments to those skilled in the art. The same reference numerals in the drawings represent the same or similar structures, and thus their detailed descriptions will be omitted. In addition, the drawings are only illustrative and are not necessarily drawn to scale.

Although relative terms such as “up” and “down” are used in this specification to describe the relative relationship between one component and another component of an icon, these terms are only used for convenience in this specification, for example, according to an example direction described in the drawings. It can be understood that if the device of the icon is flipped so that it is upside down, the component described as “up” will become the component described as “down”. When a certain structure is “on” other structures, it may mean that a structure is formed as a whole on the other structures, or a structure is “directly” arranged on the other structures, or a structure is “indirectly” arranged on the other structures through another structure.

Terms “one”, “a”, “the”, “said”, and “at least one” are used to indicate the existence of one or more elements/components/etc. Terms “include” and “has” are used to indicate open inclusion and refer to the existence of additional elements/components/etc. in addition to the listed ones. Terms “first”, “second”, and “third” are only used as reference numerals and are not intended to limit the quantity of objects.

Compared to the traditional backlight liquid crystal display (LCD), the LCD using Mini-LED backlight technology performs better in dynamic contrast and brightness, which also has advantages such as thinness, high image quality, low power consumption, and energy saving, greatly improving the performance of LCDs. The Mini-LED display panel with a larger display area is usually formed by splicing of multiple sub-display panels together. For some sub-display panels, the light-emitting unit of each sub-display panel is individually controlled by a chip, which incurs high costs.

Through the driving based on the array substrate, it is possible to use one chip to control each light-emitting unit, so that the control costs can be greatly reduced. During the production process of the array substrate, the electrostatic discharge can damage the driving circuit layer on the array substrate, especially in areas where the wiring is thinner. Electrostatic discharge can burn out some of the thin film transistors used to drive the light-emitting units, making it impossible for some light-emitting units to be driven normally, resulting in abnormal display of the display panel at these positions, and such abnormal positions cannot be repaired.

In addition, during the production process of the array substrate, it is possible to save some space using side routing, which is also one of the important ways to achieve seamless splicing. The side routing can significantly increase the screen-to-body ratio, without changing the size of the terminal. However, due to the fact that the side routing is formed by laser etching on the sputtering layer, which will cause varying degrees of damage to the front film layer of the array substrate.

The laser used in the etching process is 355 nm wavelength ultraviolet light. After the sputtering layer is etched off from the rear surface, the ultraviolet light is directly irradiated onto the channel region of the thin film transistor, causing changes in the characteristics of the active layer after the ultraviolet light is absorbed by the active layer. Specifically, the threshold voltage of the thin film transistor shifts and the off-state current increases by multiple orders of magnitude, resulting in no GOA signal output and causing defects in the display panel.

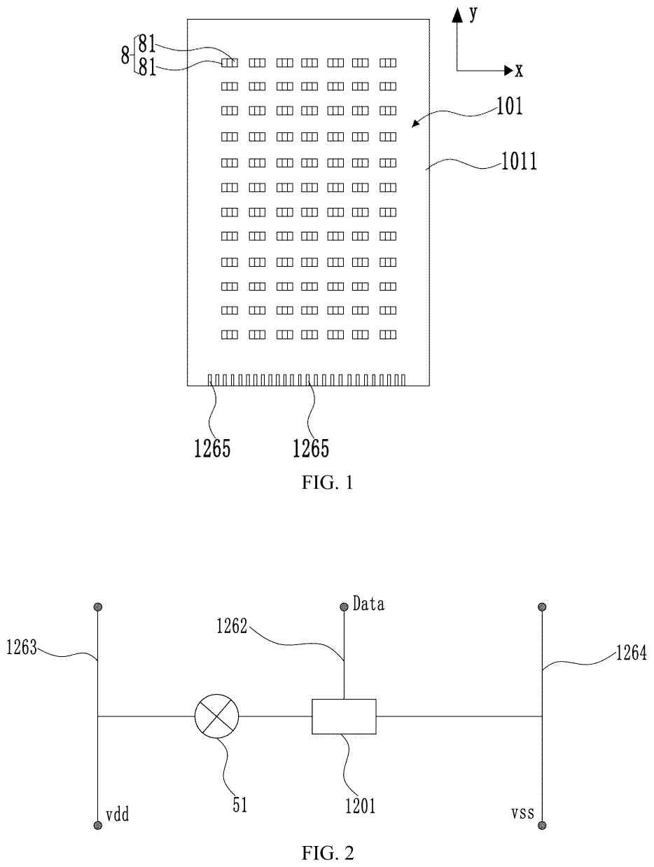

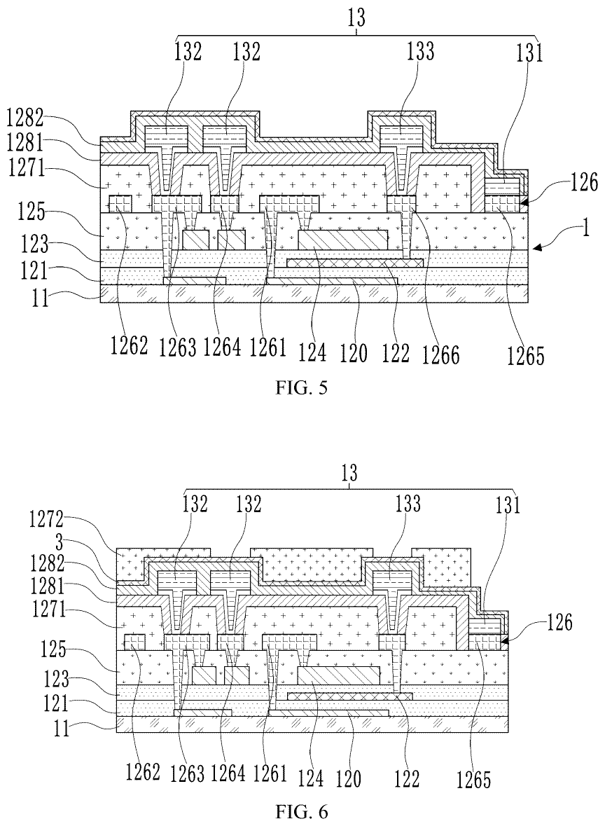

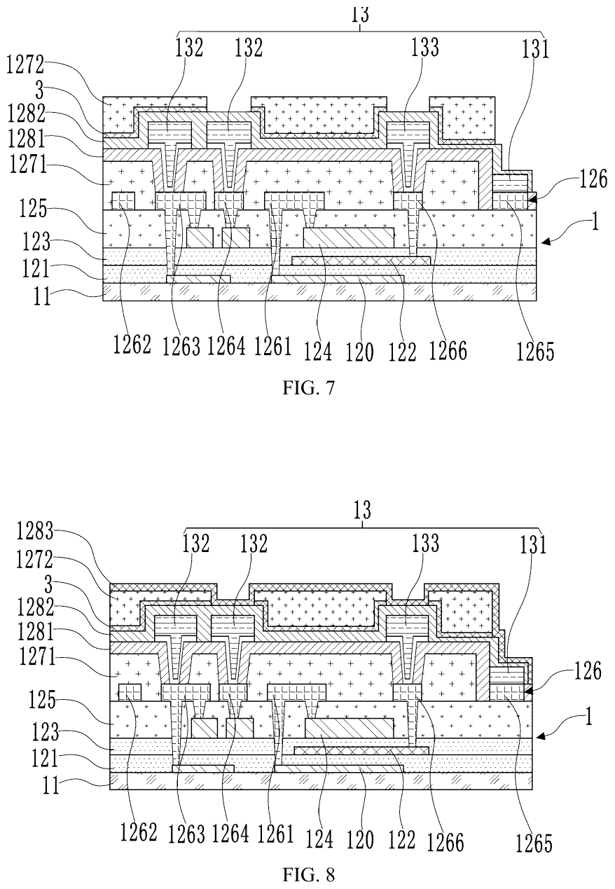

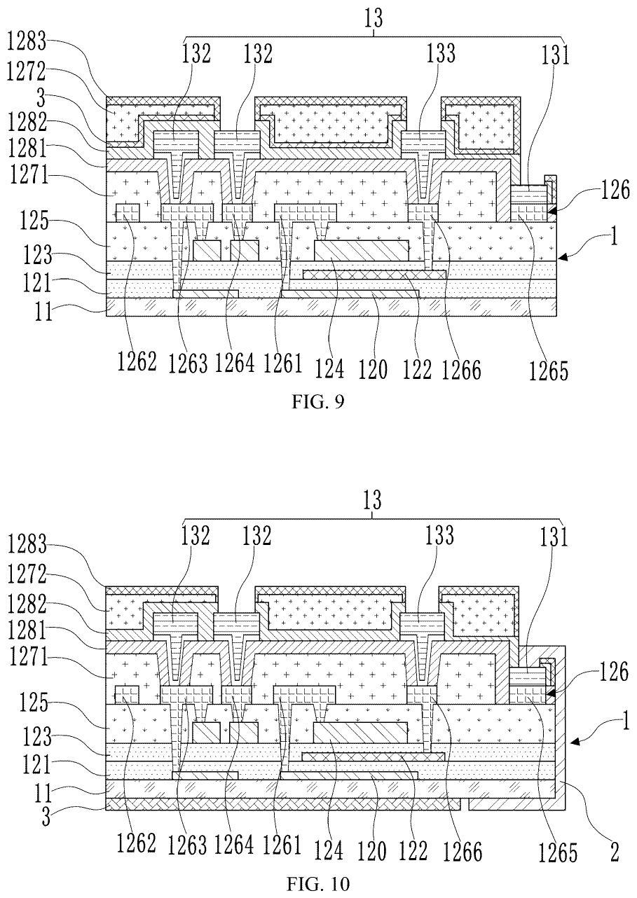

The present disclosure provides a display module. As shown in FIGS. 1 to 18, the display module includes a base substrate 11, a driving circuit layer, a first functional layer 3, and a light-emitting substrate. The driving circuit layer is arranged on a side of the base substrate 11. The first functional layer 3 is arranged on a side of the base substrate 11 away from the driving circuit layer, or the first functional layer 3 is arranged between the base substrate 11 and the driving circuit layer, or the first functional layer 3 is arranged on a side of the driving circuit layer away from the base substrate 11. The first functional layer 3 can at least release static electricity generated by the display module. The light-emitting substrate is arranged on the side of the driving circuit layer away from the base substrate 11, and the light-emitting substrate includes multiple light-emitting units.

The first functional layer 3 can release the static electricity generated during the production process of the display module, which can avoid the damage being caused by the static discharge to the circuit of the display module.

Detailed explanations of the display module involved in embodiments of the present disclosure will be provided in the following in combination with specific implementations.

As shown in FIGS. 1 to 9, the display module includes an array substrate 1, which has a driving side and a non-driving side. The array substrate 1 includes a base substrate 11 and a driving circuit layer. The driving circuit layer is arranged on the base substrate 11, serving as the driving side of the array substrate 1, and a buffer layer can also be provided between the driving circuit layer and the base substrate 11.

The display module further includes a light-emitting substrate, which is arranged on the driving side of the array substrate 1. The light-emitting substrate includes multiple light-emitting units 81 distributed in an array. The driving circuit layer is provided with driving circuits 1201 that correspond to each of the light-emitting units 81 one-to-one. Each light-emitting unit 81 is driven by the corresponding driving circuit 1201 to achieve display. Multiple first pads 131 are arranged in a display area 1011 of the display panel, and the multiple first pads 131 are arranged in sequence along a first direction. The multiple first pads 131 are used to bind driving chips or circuit boards, which input signals to the driving circuit 1201.

A first surface 101 of the display panel can include the display area 1011. The light-emitting substrate can include multiple groups 8 of light-emitting units, and each of groups 8 of light-emitting units can be disposed within the display area 1011. Each group 8 of light-emitting units includes a red light-emitting unit 81, a green light-emitting unit 81, and a blue light-emitting unit 81. It can be understood that one light-emitting unit 81 is a sub-pixel of the light-emitting substrate, and every three adjacent sub-pixels of different colors form a pixel unit. The light-emitting unit 81 can be a Mini-LED.

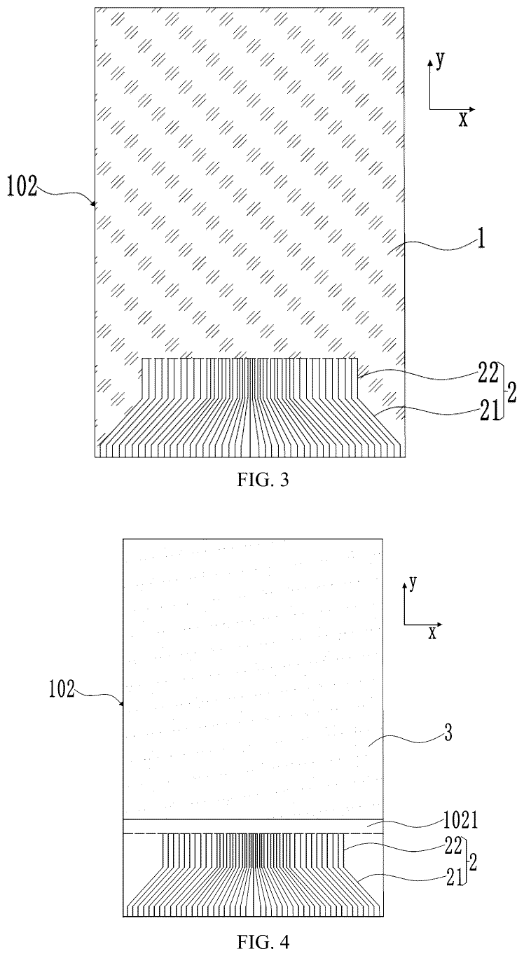

As shown in FIGS. 3 and 4, the display module further includes leading-out lines 2, and the leading-out lines 2 and the the first pads 131 are in one-to-one correspondence. The leading-out lines 2 are bound to the first pads 131. The leading-out lines 2 extend along a second direction to the edge of the array substrate 1, and bent along a third direction to a side surface of the array substrate 1. The leading-out lines 2 extend along the side surface of the array substrate 1, then extend from a first surface 101 of base substrate 11 to a second surface 102 of base substrate 11, and extend along a direction opposite to the second direction on the second surface 102 of base substrate 11, allowing the data signal line 1262 to be lead out from the first surface 101 of the base substrate 11. It should be noted that the second surface 102 of the base substrate 11 and the first surface 101 of the base substrate 11 are arranged opposite to each other.

FIGS. 3 and 4 illustrate a positional relationship between the leading-out line 2 and the first functional layer 3. The leading-out line 2 includes a fan-out leading segment 21 and a binding leading segment 22. Along the extension direction of the leading-out line 2, the fan-out leading segment 21 inclines along the first direction from both sides of the base substrate 11 towards the middle, forming a fan-shaped first routing area. The binding leading segment 22 is arranged at one end of the fan-out leading segment 21 away from the end connected to the leading-out line 2. The binding leading segment 22 extends along the direction opposite to the second direction. Multiple binding leading segments 22 are parallel to each other. The binding leading segment 22 is used to be bound to the driving chip or the binding circuit board.

It should be noted that a sputtering layer can be formed on the second surface 102 and the side surface of the base substrate 11. By setting process parameters, the sputtering layer can be formed in one process. The sputtering layer is patterned by laser etching to form the fan-out leading segment 21 and the binding leading segment 22. The first direction is the x direction, and the second direction is the y direction. The third direction is perpendicular to both the first direction and the second direction, that is, the third direction is the thickness direction of the display module.

The leading-out line 2 extends from the side surface of the array substrate 1 to the second surface of the array substrate 1, and the leading-out line 2 is formed using sputtering and laser etching processes, not only achieving the conductivity connection between the first pad 131 on the driving side of the array substrate 1 and the binding pin, but also eliminating the need to reserve an arrangement area for the leading-out line 2 in the binding area on the driving side, and reducing the width of the binding area.

The driving circuit layer includes a driving circuit 1201, a data signal line 1262, a common ground signal line 1264, and a power signal line 1263. The driving circuit 1201 and the light-emitting unit 81 are connected in series between the power signal line 1263 and the common ground signal line 1264. The output terminal of the data signal line 1262 is connected to the driving circuit 1201.

When the array substrate 1 is in operation, a reference voltage signal is provided to the light-emitting unit 81 through the common ground signal line 1264, and a power voltage signal is provided to the light-emitting unit 81 through the power signal line 1263. A voltage difference is generated between the power voltage signal and the reference voltage signal, causing the light-emitting unit 81 to emit light.

The driving current of the light-emitting unit 81 is controlled by the driving circuit 1201, and the data signal line 1262 inputs a data signal to the driving circuit 1201. The data signal is used to control the magnitude of the driving current provided by the driving circuit 1201 or the duration during which the driving current is loaded, thereby achieving the purpose of controlling the brightness of the light-emitting unit 81.

The base substrate 11 can be an inorganic material base substrate or an organic material base substrate. For example, in some embodiments of the present disclosure, the material of the base substrate 11 can be glass materials such as soda-lime glass, quartz glass, sapphire glass, etc., or metal materials such as stainless steel, aluminum, nickel, etc.

In some embodiments of the present disclosure, the material of the base substrate 11 can be polymethyl methacrylate (PMMA), polyvinyl alcohol (PVA), polyvinyl phenol (PVP), polyether sulfone (PES), polyimide, polyamide, polyacetal, polycarbonate (PC), polyethylene terephthalate (PET), polyethylene naphthalate (PEN), or a combination thereof.

In some embodiments of the present disclosure, the base substrate 11 can also be a flexible base substrate, for example, the material of the base substrate 11 can be polyimide (PI). The base substrate 11 can also be a composite structure of multiple layers of materials. For example, in some embodiments, the base substrate 11 can include a bottom film layer, a pressure-sensitive adhesive layer, a first polyimide layer, and a second polyimide layer stacked in sequence.

In the driving circuit layer, the driving circuit 1201 can include a transistor. Furthermore, the transistor can be a thin film transistor, which can be a double gate thin film transistor. The material of the active layer 122 of the thin film transistor can be amorphous silicon semiconductor materials, low-temperature polycrystalline silicon semiconductor materials, metal oxide semiconductor materials, organic semiconductor materials, or other types of semiconductor materials. The driving circuit can also include other circuit structures, such as storage capacitors.

The transistor can have a first terminal, a second terminal, and a control terminal. One of the first terminal and the second terminal can be a source of the transistor, and the other can be a drain of the transistor. The control terminal can be a gate of the transistor. It can be understood that the source and the drain of the transistor are two opposing and interchangeable concepts. When the operating state of the transistor changes, such as when a direction of the current changes, the source and the drain of the transistor can be interchanged.

The double gate thin film transistor is taken as an example to explain the driving circuit layer. The driving circuit layer can include a first gate layer 120, a first gate insulation layer 121, an active layer 122, a second gate insulation layer 123, a second gate layer 124, an interlayer dielectric layer 125, and a first metal layer 126.

The first gate layer 120 is arranged on a side of the base substrate 11, the first gate insulation layer 121 is arranged on a side of the first gate layer 120 away from the base substrate 11 and the first gate insulation layer 121 covers both the first gate layer 120 and the base substrate 11. The active layer 122 is arranged on a side of the first gate insulation layer 121 away from the base substrate 11, the second gate insulation layer 123 is arranged on a side of the active layer 122 away from the base substrate 11, and the second gate insulation layer 123 can cover both the active layer 122 and the first gate insulation layer 121. The second gate layer 124 is arranged on a side of the second gate insulation layer 123 away from the base substrate 11. The materials of the first gate insulation layer 121 and the second gate insulation layer 123 are insulation materials such as silicon oxide, and the material of the active layer 122 can be polycrystalline silicon, amorphous silicon, etc.

The active layer 122 can include a channel region and a source region and a drain region arranged on both sides of the channel region, two doped regions with different types of doped materials. The channel region can maintain semiconductor characteristics, and the semiconductor materials in the source and drain regions are partially or completely conductive. The first gate layer 120 includes the first gate of the thin film transistor, and a projection of the first gate on the base substrate 11 overlaps with a projection of the active layer 122 on the base substrate 11. The projection of the first gate on the base substrate 11 at least coincides with a projection of the channel region of the active layer 122 on the base substrate 11. The second gate layer 124 includes the second gate of the thin film transistor, which is directly opposite to the active layer 122. That is, a projection of the second gate on the base substrate 11 is arranged within a range of the projection of the active layer 122 on the base substrate 11. For example, the projection of the second gate on the base substrate 11 coincides with the projection of the channel region of the active layer 122 on the base substrate 11.

The array substrate 1 further includes an interlayer dielectric layer 125, which is arranged on a side of the second gate layer 124 away from the base substrate 11. The interlayer dielectric layer 125 covers the second gate layer 124 and the second gate insulation layer 123. The interlayer dielectric layer 125 is made of an insulation material. The first metal layer 126 includes a source 1261 and a drain 1266 of the thin film transistor. The source 1261 and the drain 1266 are arranged on a surface of the interlayer dielectric layer 125 away from the base substrate 11. The source 1261 and the drain 1266 are connected to the active layer 122. In some embodiments, the source 1261 and the drain 1266 are respectively connected to the corresponding source and drain regions of the active layer 122 through via holes.

The first metal layer 126 can further include a power signal line 1263, a common ground signal line 1264, and a data signal line 1262. The power signal line 1263 can be connected to the first gate layer 120 and the second gate layer 124 simultaneously. The common ground signal line 1264 can be connected to the second gate layer 124, and the common ground signal line 1264 is electrically connected to the cathode of the light emitting unit 81. The power signal line 1263 is connected to the anode of the light emitting unit 81. The data signal line 1262 can be connected to the source 1261 or the drain 1266 of the thin film transistor.

The array substrate 1 has a binding area, and the binding area is located on a side of the interlayer dielectric layer 125 away from the base substrate 11. The binding area is provided with a first conductive part 1265, and the first conductive part 1265 is located at an edge of the interlayer dielectric layer 125. The data signal line 1262 is led out from the array substrate 1 by using the first conductive part 1265.

The first conductive part 1265, the data signal line 1262, the power signal line 1263, and the common ground signal line 1264 are located in the first metal layer 126 and can be arranged in the same layer as the source 1261 and the drain 1266 of the thin film transistor. In other words, the materials of the first conductive part 1265, the data signal line 1262, the power signal line 1263, and the common ground signal line 1264 can be the same as the materials of the source and the drain electrodes of the thin film transistor, and can be formed together in one patterning process.

The array substrate 1 further includes a first planarization layer 1271, which is arranged on a side where the source 1261, the drain 1266, the data signal line 1262, the power signal line 1263, and the common ground signal line 1264 are away from the base substrate 11. The first planarization layer 1271 covers the source 1261, the drain 1266, the data signal line 1262, the power signal line 1263, the common ground signal line 1264, and the interlayer dielectric layer 125. The array substrate 1 further includes a first protective layer 1281, which is arranged on a side of the first planarization layer 1271 away from the base substrate 11. The first protective layer 1281 covers the first planarization layer 1271, and is in contact with the source 1261, the drain 1266, the power signal line 1263, and the common ground signal line 1264.

A second metal layer 13 is provided on a side of the first protective layer 1281 away from the base substrate 11. The second metal layer 13 includes a first pad 131, a second pad 132, and a third pad 133. The second pad 132 is connected to the power signal line 1263 and the common ground signal line 1264 through via holes, respectively. The third pad 133 is connected to the source 1261 or the drain 1266 of the thin film transistor through via holes. The second pad 132 connected to the common ground signal line 1264 can be electrically connected to the cathode of the light-emitting unit 81, and the second pad 132 connected to the power signal line 1263 can be connected to the anode of the light-emitting unit 81.

The array substrate 1 further includes a second protective layer 1282, which is arranged on a side where the first pad 131, the second pad 132, and the third pad 133 are away from the base substrate 11. The second protective layer 1282 covers the first protective layer 1281, a portion of the first pad 131, a portion of the second pad 132, and a portion of the third pad 133. The exposed portion of the second pad 132 is connected to the light-emitting unit 81, and the exposed portion of the third pad 133 is connected to the light-emitting unit 81.

The array substrate 1 can further include a second planarization layer 1272, which is arranged on a side of the second protective layer 1282 away from the base substrate 11. The second planarization layer 1272 covers a portion of the second protective layer 1282, and a surface of the second planarization layer 1272 away from the base substrate 11 is flat. The second planarization layer 1272 exposes the first pad 131, a portion of the second pad 132, and a portion of the third pad 133.

The array substrate 1 can further include a third protective layer 1283, which is arranged on a side of the second planarization layer away from the base substrate 11, exposing a portion of the third pad 133 and a portion of the second pad 132. Because there is no second protective layer 1282 formed on the first pad 131 located at the edge of the array substrate 1, the third protective layer 1283 at this location is formed on the second protective layer 1282, exposing the first pad 131.

To ensure the electro-static discharge (ESD) capability of the display module, a structure of the display module needs to be able to release the static electricity on the display panel. The array substrate 1 can further include a first functional layer 3, which is arranged between the third protective layer 1283 and the second planarization layer 1272. The first functional layer 3 can be a transparent electrode layer with a thickness of 10 nm-70 nm. The process of adding a transparent material layer to the front of the existing display modules is simple and easy to be implemented, without the need for additional mask plates, and thus resulting in lower costs. It should be noted that the material of the transparent electrode layer can be at least one of ITO, IGZO, or IZO.

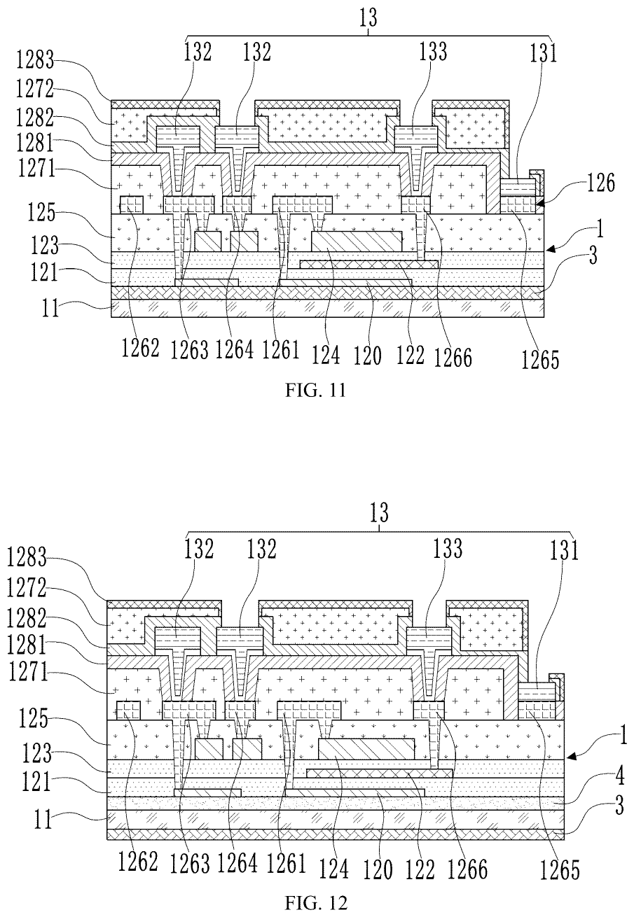

As shown in FIG. 10, the first functional layer 3 can also be arranged on a side of the base substrate 11 away from the first gate layer 120. As shown in FIG. 11, the first functional layer 3 can also be arranged between the base substrate 11 and the first gate layer 120. The first functional layer 3 can be a transparent electrode layer with a thickness of 10 nm-70 nm. The first functional layer 3 can guide away the static electricity generated by the friction between the array substrate 1 and the equipment machine, as well as the static electricity generated during the film sticking process and the film tearing process, which can improve the anti-static ability of the array substrate 1 by 80%.

When the first functional layer 3 is arranged on the side of the base substrate 11 away from the first gate layer 120, a mask plate needs to be provided when forming the first functional layer 3, to avoid the leading-out line 2 located on the array substrate 1, a purpose of which is to prevent a short circuit between the leading-out line 2 and the first functional layer 3. It should be noted that the leading-out line 2 includes fan-out leading lines and binding leading lines.

It should be noted that when the array substrate 1 only includes a transparent electrode layer, it is necessary to reduce the damage of the laser to the array substrate 1 in combination with the laser etching process optimization. The double gate thin film transistor can absorb some of the energy of the laser etching process.

As shown in FIG. 12, when the first functional layer 3 is arranged on the side of the base substrate 11 away from the first gate layer 120, a second functional layer 4 can also be provided between the base substrate 11 and the first gate layer 120. The second functional layer 4 is an amorphous silicon layer. When forming side traces, the second functional layer 4 can absorb some of the energy of the laser etching process to prevent the damage to the front film layer caused by the laser etching process. It is expected that the laser damage can be reduced by 40%. It can be understood that the first functional layer 3 can also be provided between the base substrate 11 and the first gate layer 120, and the second functional layer 4 is arranged on the side of the base substrate 11 away from the first gate layer 120. It should be noted that the first functional layer 3 can also be provided as a p-type doped amorphous silicon layer, an n-type doped amorphous silicon layer, or a conductive low-temperature polycrystalline silicon layer.

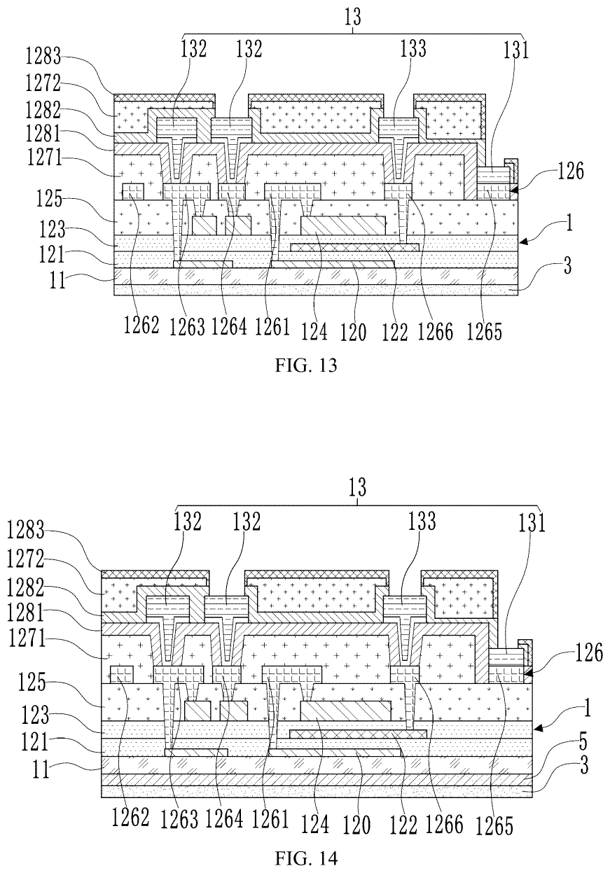

As shown in FIG. 13, the first functional layer 3 is arranged on the side of the base substrate 11 away from the first gate layer 120. The first functional layer 3 is a p-type doped amorphous silicon layer or an n-type doped amorphous silicon layer, which can increase the resistance of the array substrate 1. The first functional layer 3 can also absorb some of the energy of the laser etching process to prevent the damage to the front film layer caused by the laser etching process. It is expected that the laser damage can be reduced by 40%.

The n-type doped amorphous silicon layer can be formed when the n-type doping is performed on the amorphous silicon layer, and the p-type doped amorphous silicon layer can be formed when the p-type doping is performed on the amorphous silicon layer. Both the n-type doped amorphous silicon layer and the p-type doped amorphous silicon layer can have anti-static effects. When the first functional layer 3 is the p-type doped amorphous silicon layer or the n-type doped amorphous silicon layer, the first functional layer 3 has extremely low parasitic capacitance relative to the front circuit.

When the first functional layer 3 is the p-type doped amorphous silicon layer or the n-type doped amorphous silicon layer, the thickness of the first functional layer 3 is 10 nm-50 nm. It should be noted that the dehydrogenation usually needs to be carried out on the amorphous silicon layer to slowly release the hydrogen in the amorphous silicon layer, thereby reducing the hydrogen content of the amorphous silicon layer with a higher hydrogen content to the hydrogen content below 2%, and preventing the hydrogen explosion (i.e. violent release of a large amount of hydrogen within a short period) during the laser irradiation from occurring on the amorphous silicon layer, which can cause the amorphous silicon layer to rupture, cannot play the anti-static effects, and cannot reduce the laser damage to the array substrate 1.

As shown in FIG. 14, when the first functional layer 3 is arranged on the side of the base substrate 11 away from the first gate layer 120, a first buffer layer 5 can be provided between the first functional layer 3 and the base substrate 11. The purpose of providing the first buffer layer 5 is to increase the adhesion between the driving circuit layer and the base substrate 11. The material of the first buffer layer 5 can be SiNx, SiOx or a composite layer of SiNx and SiOx. The SiOx is preferred for the first buffer layer 5. The thickness of the first buffer layer 5 is 20 nm-100 nm.

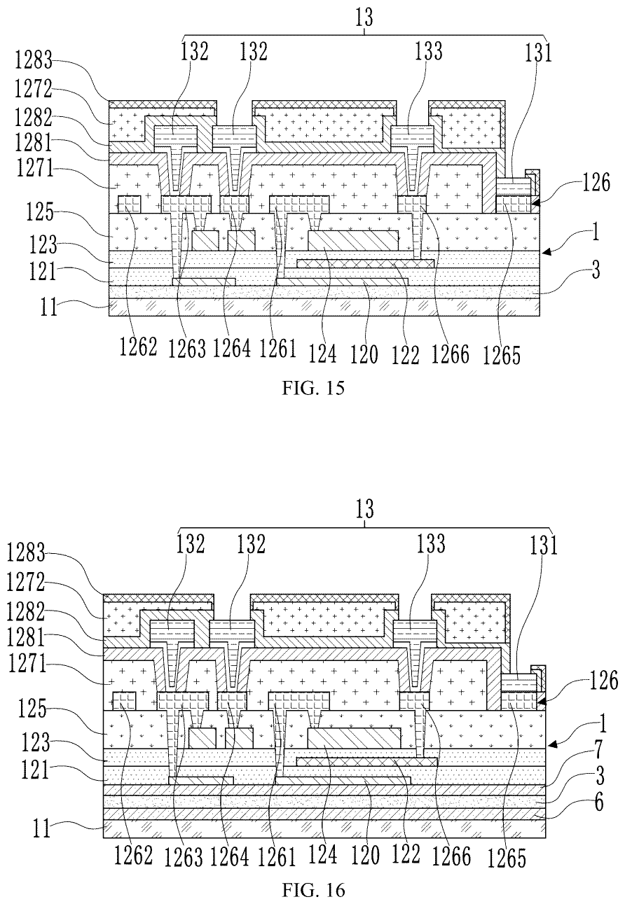

As shown in FIG. 15, the first functional layer 3 can also be provided between the base substrate 11 and the driving circuit layer. As shown in FIG. 16, when the first functional layer 3 is provided between the base substrate 11 and the driving circuit layer, a second buffer layer 6 can be provided between the base substrate 11 and the first functional layer 3, and a third buffer layer 7 can be provided between the first functional layer 3 and the driving circuit layer. The function of the second buffer layer 6 is to increase the adhesion between the driving circuit layer and the base substrate 11, and the function of the third buffer layer 7 is to form the insulation between the first functional layer 3 and the driving circuit layer. The thickness of the second buffer layer 6 and the thickness of the third buffer layer 7 are both 20 nm-100 nm.

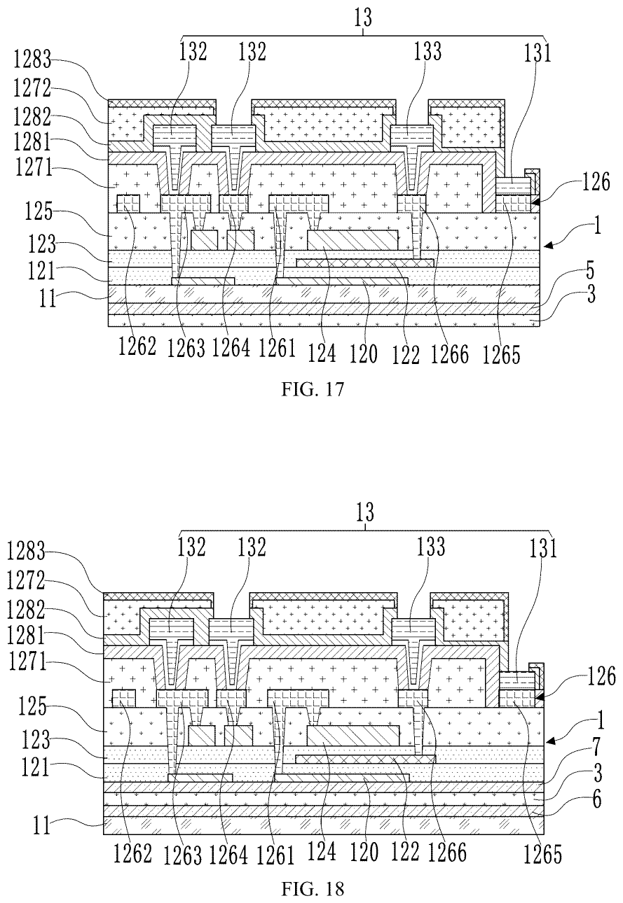

The array substrate 1 only includes a first functional layer 3. The first functional layer 3 is a conductive low-temperature polycrystalline silicon layer with a thickness of 20 nm-50 nm. As shown in FIG. 17, the first functional layer 3 can be arranged on the side of the base substrate 11 away from the driving circuit layer, and the first functional layer 3, likewise, has extremely low parasitic capacitance relative to the front circuit. As shown in FIG. 18, the first functional layer 3 can also be provided between the base substrate 11 and the driving circuit layer.

When the first functional layer 3 is arranged on the side of the base substrate 11 away from the driving circuit layer, a first buffer layer 5 is provided between the first functional layer 3 and the base substrate 11, to increase the adhesion between the driving circuit layer and the base substrate 11. When the first functional layer 3 is provided between the base substrate 11 and the driving circuit layer, a second buffer layer 6 is provided between the base substrate 11 and the first functional layer 3, and a third buffer layer 7 is provided between the first functional layer 3 and the driving circuit layer. The function of the second buffer layer 6 is to increase the adhesion between the driving circuit layer and the base substrate 11, and the function of the third buffer layer 7 is to form the insulation between the first functional layer 3 and the driving circuit layer. The thickness of the first buffer layer 5, the thickness of the second buffer layer 6, and the thickness of the third buffer layer 7 are all 100 nm-300 nm.

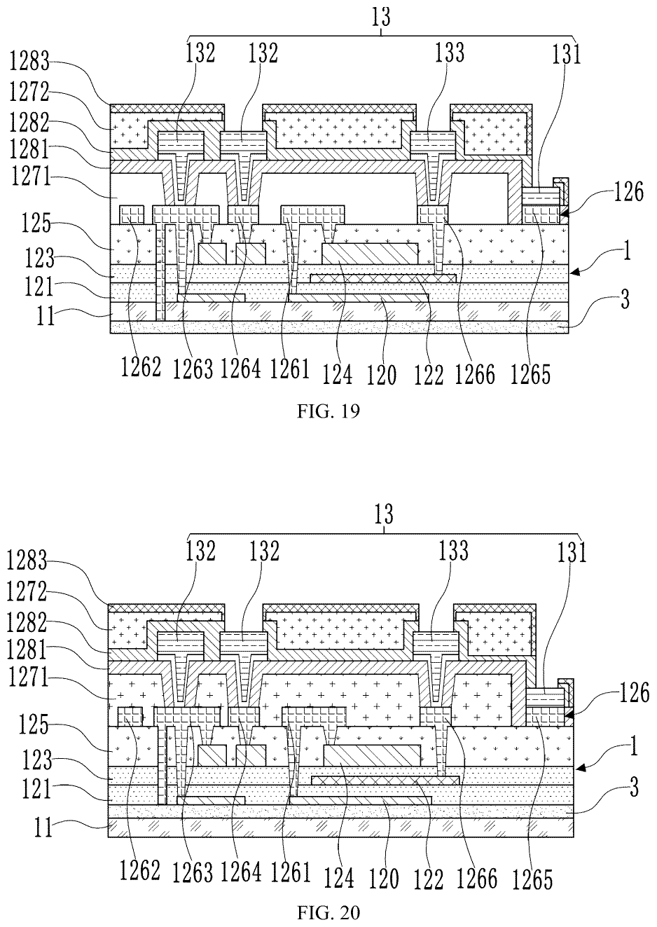

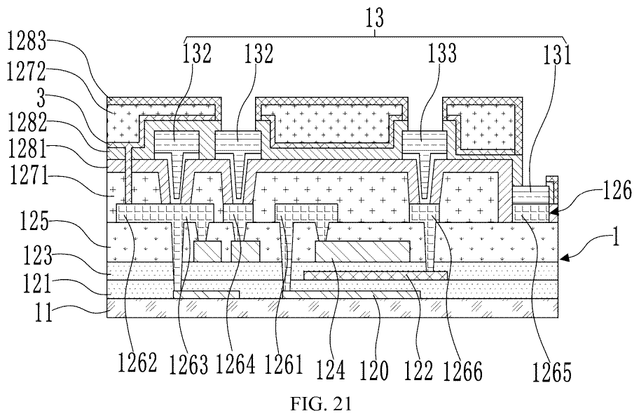

As shown in FIGS. 19 to 21, regardless of whether the first functional layer 3 is located on the rear surface of the base substrate 11, or located between the base substrate 11 and the driving circuit layer, or located on the side of the driving circuit layer away from the base substrate 11, the first functional layer 3 can always be electrically connected to the power signal line 1263 through via holes, to avoid the unstable electric potential caused by a suspension potential, which is caused by the static electricity due to the suspension of the first functional layer 3, ensuring the stability of the performance of the thin film transistor, thereby ensuring the display effect. In some embodiments, the first functional layer 3 can also be electrically connected to the common ground signal line 1264 through via holes.

When the first functional layer 3 is formed on the side of the base substrate 11 away from the driving circuit layer, an amorphous silicon layer is first deposited on the side of the base substrate 11 away from the driving circuit layer, and the amorphous silicon layer is dehydrogenated. Then, the Excimer Laser Annealing (ELA) device is used to irradiate the amorphous silicon layer with laser to convert the amorphous silicon layer into a low-temperature polycrystalline silicon layer. The low-temperature polycrystalline silicon layer is then heavily doped to make it conductive. When the first functional layer 3 is a conductive low-temperature polycrystalline silicon layer, it can block laser etching damage and prevent electrostatic discharge damage. The procedure of forming the first functional layer 3 on the side of the base substrate 11 close to the driving circuit layer is the same as the above procedure, and will not be repeated here.

Reference is made again to FIG. 3, when the first functional layer 3 is located between the base substrate 11 and the driving circuit layer, or arranged on the side of the driving circuit layer away from the base substrate 11, the leading-out line 2 can be directly formed on the second surface 102 of the base substrate 11. Reference is made again to FIG. 4, when the first functional layer 3 is located on the side of the base substrate 11 away from the driving circuit layer, there is a gap 1021 between the first functional layer 3 and the leading-out line 2, to prevent a short circuit between the leading-out line 2 and the first functional layer 3.

Embodiments of the present disclosure also provide a display apparatus. The display apparatus can include any of the display modules described in the above embodiments. The specific structures and beneficial effects of the display module have been explained in detail in the above, which will not be repeated here.

It should be noted that in addition to the display module, the display apparatus further includes other necessary components and compositions, such as circuit boards, power cords, etc. Those skilled in the art can supplement the components and compositions according to the specific usage requirements of the display apparatus, which will not be repeated here.

The display apparatus can be traditional electronic devices, such as mobile phones, computers, televisions, and video cameras, which will not be listed one by one here. The number of display modules included in the display apparatus can be multiple, and the multiple display modules can be spliced together to form a larger display area. The display module has no borders, and thus it will not affect the display effect of the display apparatus after splicing.

After considering the specification and practicing of the invention disclosed herein, those skilled in the art will easily come up with other implementation solutions of the present disclosure. The present disclosure aims to cover any variations, uses, or adaptive changes of the present disclosure, which follow the general principles of the present disclosure and include common knowledge or commonly used technical means in the art that are not disclosed in the present disclosure. The specification and embodiments are only considered exemplary, and the true scope and spirit of the present disclosure are

1. A display module, comprising:
a base substrate;
a driving circuit layer arranged on a side of the base substrate;
a first functional layer arranged in one of following ways: on a side of the base substrate away from the driving circuit layer, between the base substrate and the driving circuit layer, or on a side of the driving circuit layer away from the base substrate, wherein the first functional layer can at least release static electricity generated by the display module; and
a light-emitting substrate arranged on the side of the driving circuit layer away from the base substrate, wherein the light-emitting substrate comprises multiple light-emitting units.

2. The display module according to claim 1, wherein the first functional layer is one of a p-type doped amorphous silicon layer, an n-type doped amorphous silicon layer, a conductive low-temperature polycrystalline silicon layer, or a transparent electrode layer.

3. The display module according to claim 2, wherein in the case that the first functional layer is one of the transparent electrode layer, the p-type doped amorphous silicon layer, the n-type doped amorphous silicon layer, or the conductive low-temperature polycrystalline silicon layer, the first functional layer is arranged in one of following ways: on the side of the base substrate away from the driving circuit layer or between the base substrate and the driving circuit layer.

4. The display module according to claim 3, wherein in the case that the first functional layer is arranged on the side of the base substrate away from the driving circuit layer, a first buffer layer is provided between the first functional layer and the base substrate.

5. The display module according to claim 3, wherein in the case that the first functional layer is arranged between the base substrate and the driving circuit layer, a second buffer layer is provided between the base substrate and the first functional layer, and a third buffer layer is provided between the first functional layer and the driving circuit layer.

6. The display module according to claim 3, wherein in the case that the first functional layer is the transparent electrode layer, the display module further comprises a second functional layer, and wherein the second functional layer is arranged in one of following ways: on the side of the base substrate away from the driving circuit layer, or between the base substrate base substrate and the driving circuit layer, and the second functional layer is configured to prevent laser etching from damaging the driving circuit layer.

7. The display module according to claim 6, wherein the second functional layer is one of an amorphous silicon layer, the p-type doped amorphous silicon layer, the n-type doped amorphous silicon layer, or the conductive low-temperature polycrystalline silicon layer.

8. The display module according to claim 2, wherein the driving circuit layer comprises a driving circuit, a data signal line, a common ground signal line, and a power signal line, the driving circuit and the light-emitting unit are connected in series between the power signal line and the common ground signal line, and an output end of the data signal line is connected to the driving circuit; and
wherein the driving circuit layer further comprises a transistor layer, the transistor layer comprises a thin film transistor, and the thin film transistor is a double gate thin film transistor.

9. (canceled)

10. The display module according to claim 8, wherein the driving circuit layer further comprises a first metal layer, the first metal layer is arranged on a side of the transistor layer away from the base substrate, and the data signal line, the power signal line, and the common ground signal line are located in the first metal layer.

11. The display module according to claim 10, wherein the first metal layer further comprises a first conductive part, the first conductive part is connected to the data signal line, the first conductive part is located at an edge of the first metal layer, and the first conductive part is configured to be connected with a leading-out line.

12. The display module according to claim 9, wherein the first functional layer is connected to one of the power signal line or the common ground signal line through a via hole.

13. The display module according to claim 11, wherein the driving circuit layer further comprises an interlayer dielectric layer, and the interlayer dielectric layer is provided between the first metal layer and the transistor layer.

14. The display module according to claim 13, wherein the display module further comprises a second metal layer, the second metal layer is arranged on a side of the interlayer dielectric layer away from the base substrate, the second metal layer comprises a second pad and a third pad, the second pad is connected to the power signal line and the common ground signal line respectively through via holes, and the third pad is connected to a source or a drain of the thin film transistor through a via hole.

15. The display module according to claim 14, wherein the second metal layer further comprises a first pad, the first pad is stacked on a side of the first conductive part away from the base substrate, and the first pad is configured to be connected with the leading-out line.

16. The display module according to claim 15, further comprising:
a first planarization layer, wherein the first planarization layer is provided between the second metal layer and the first metal layer, the first planarization layer partially covers the first metal layer and the interlayer dielectric layer, and exposes the first conductive part; and
a first protective layer, wherein the first protective layer is provided between the first planarization layer and the second metal layer, the first protective layer covers the first planarization layer and the interlayer dielectric layer, and exposes the first conductive part.

17. (canceled)

18. The display module according to claim 16, further comprising:
a second protective layer, wherein the second protective layer is arranged on a side of the second metal layer away from the base substrate, and the second protective layer covers the first protective layer, a portion of the first pad, a portion of the second pad, and a portion of the third pad: and
a second planarization layer, wherein the second planarization layer is arranged on a side of the second protective layer away from the base substrate, the second planarization layer covers the second protective layer, a surface of the second planarization layer away from the base substrate is flat, and the second planarization layer exposes a portion of the third pad and a portion of the second pad.

19. (canceled)

20. The display module according to claim 18, wherein the display module further comprises a third protective layer, the third protective layer is arranged on a side of the second planarization layer away from the base substrate, and the third protective layer exposes a portion of the third pad and a portion of the second pad.

21. The display module according to claim 20, wherein in the case that the first functional layer is the transparent electrode layer, the first functional layer is provided between the third protective layer and the second planarization layer.

22. The display module according to claim 15, wherein the leading-out line is bound to the first pad, and extends along a side surface of the driving circuit layer and a side surface of the base substrate to a side of the base substrate away from the driving circuit, and where the leading-out line is formed by laser etching a sputtering layer.

23. A display apparatus comprising a display module,
wherein the display module comprises:
a base substrate;
a driving circuit layer arranged on a side of the base substrate;
a first functional layer arranged in one of following ways: on a side of the base substrate away from the driving circuit layer, between the base substrate and the driving circuit layer, or on a side of the driving circuit layer away from the base substrate, wherein the first functional layer can at least release static electricity generated by the display module; and
a light-emitting substrate arranged on the side of the driving circuit layer away from the base substrate, wherein the light-emitting substrate comprises multiple light-emitting units.
